(19) United States
(12) Patent Application Publication
(10) Pub. No.: US 2026/0182326 A1
(43) Pub. Date: Jun. 25, 2026

(54) Methods for Processing Substrates

(71) Applicant: Applied Materials, Inc., Santa Clara, CA (US)

(72) Inventor: Michael CHUDZIK, Mountain View, CA (US)

(21) Appl. No.: 19/014,567

(22) Filed: Jan. 9, 2025

Related U.S. Application Data
(60) Provisional application No. 63/737,566, filed on Dec. 20, 2024.

(51) Int. Cl. H01L 21/768

(52) U.S. Cl. CPC H10W 20/075; H10W 20/084

(57) ABSTRACT

Methods for substrate processing include: forming a first multi-layered structure on a first carrier, wherein the first multi-layered structure includes a first top layer including a first core material and at least one first via extending through the first core material; forming a second multi-layered structure on a second carrier, wherein the second multi-layered structure includes a second top layer including a second core material and at least one second via extending through the second core material; bonding the first top layer to the second top layer so that the first via and the second via align and are connected; and after bonding, separating the first carrier from the first multi-layered structure, and separating the second carrier from the second multi-layered structure.

### CROSS-REFERENCE TO RELATED APPLICATIONS

This application claims priority to U.S. Provisional Application 63/737,566, filed Dec. 20, 2024, the entire contents of which are incorporated herein by reference.

### FIELD

Embodiments of the present disclosure generally relate to methods and systems for processing substrates, and more particularly, for processing substrates with a rigid core.

### BACKGROUND

Some integrated circuits are created by double sided processing of semiconductor substrates. For example, distribution layers may be deposited on opposite sides of a single substrate, which acts as a core. Conductive vias are also typically formed through the thickness of the core. Since the resistance of the vias depends on length of the vias, thicker cores and longer vias may result in higher resistance of the vias in comparison to thinner cores and shorter vias.

However, to enable double sided processing, the core is both double sided processed in some cases and in other cases is flipped to deposit layers on both sides of the core. To prevent damage to the core from flipping and handling, the core may have a thickness based largely on a rigidity requirement as measured by bow, rather than on optimizing thickness to reduce resistance of vias.

Also, double sided processing of advanced substrates typically deposits an organic redistribution layer (RDL) before an inorganic redistribution layer deposition (RDL), which may be a final layer (e.g., an inorganic dual damascene layer). The deposition of an inorganic RDL typically requires a processing environment that is cleaner than a processing environment for the deposition of an organic RDL. As a result, downstream fabricators who deposit the inorganic RDL may move fabrication to a facility with a cleaner environment at increased cost for completion of the double-sided processing.

Further, because double-sided processing builds layers on both sides of the core, the core cannot be customized or modified during later stages of fabrication.

Thus, methods are proposed that employ single-sided processing that can reduce resistance of vias and thickness of the core, allow for the downstream fabrication to be performed in environments with cleaning standards that are less stringent, facilitate embedding features into the core, and/or allow for the core material to be selected after fabrication has begun.

### SUMMARY

Methods for substrate processing are provided herein. In some embodiments, a method for substrate processing includes: forming a first multi-layered structure on a first carrier, wherein the first multi-layered structure includes a first top layer including a first core material and at least one first via extending through the first core material; forming a second multi-layered structure on a second carrier, wherein the second multi-layered structure includes a second top layer including a second core material and at least one second via extending through the second core material; bonding the first top layer to the second top layer so that the first via and the second via align and are connected; and after bonding, separating the first carrier from the first multi-layered structure (e.g., with a debonding or grind/removal process), and separating the second carrier from the second multi-layered structure (e.g., with a debonding or grind/removal process).

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 shows a method for substrate processing in accordance with some embodiments of the present disclosure.

FIG. 2 is a schematic showing two multi-layered structures in accordance with some embodiments of the present disclosure.

FIG. 3 is a schematic showing the two multi-layered structures of FIG. 2 bonded together in accordance with some embodiments of the present disclosure.

FIG. 4 is a schematic showing separation of carriers from the two multi-layered structures of FIG. 3 in accordance with some embodiments of the present disclosure.

FIG. 5 is a schematic representation of a carrier in accordance with some embodiments of the present disclosure.

FIG. 6 is a schematic representation showing an inorganic redistribution layer formed on the carrier shown in FIG. 5 in accordance with some embodiments of the present disclosure.

FIG. 7 is a schematic representation showing an organic redistribution layer formed on the inorganic redistribution layer shown in FIG. 6 in accordance with some embodiments of the present disclosure.

FIG. 8 is a schematic representation showing a core material of a top layer formed on the organic redistribution layer shown in FIG. 7 in accordance with some embodiments of the present disclosure.

FIG. 9 is a schematic representation showing vias formed in the core material of the top layer shown in FIG. 8 in accordance with some embodiments of the present disclosure.

FIG. 10 is a schematic representation showing features embedded in the top layer shown in FIG. 9 in accordance with some embodiments of the present disclosure.

FIG. 11 is a schematic representation of a chip packaging substrate in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

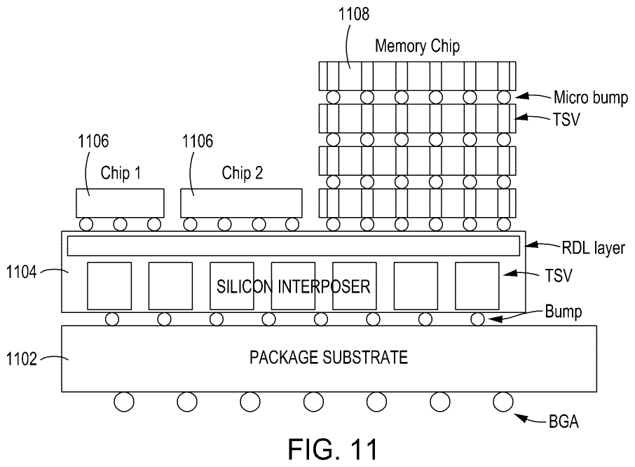

Embodiments of a method for substrate processing are provided herein. In some embodiments, the substrates described herein may be chip package substrates such as chip package substrate 1102 shown in FIG. 11, which may be connected to a silicon interposer 1104 connected to various chips 1106 and memory chips 1108.

The methods in accordance with the present disclosure replace the double-sided processing discussed above with single sided processing for package substrates, by effectively dividing the fabrication of the core and the layers attached on both sides of the core into two multi-layered structures which can be bonded together at the core. The methods described in accordance with the present disclosure enable a thinner core which can improve resistance through vias formed in the core. Also, the methods described herein enable inorganic redistribution layers (RDL) to be deposited before organic RDL on each of the two multi-layered structures, which can allow downstream fabrication in environments with less stringent cleanliness requirements. In addition, the methods described herein may allow reuse of carriers used to fabricate each of the two multi-layered structures, which can result in cost savings and reduced material waste. Also, the methods described herein allow the core material to be deposited as a top layer of each of the two multi-layered structures. As a result, the core material may be easily changed or customized in a deposition process (e.g., sputter deposition) at a later stage of fabrication.

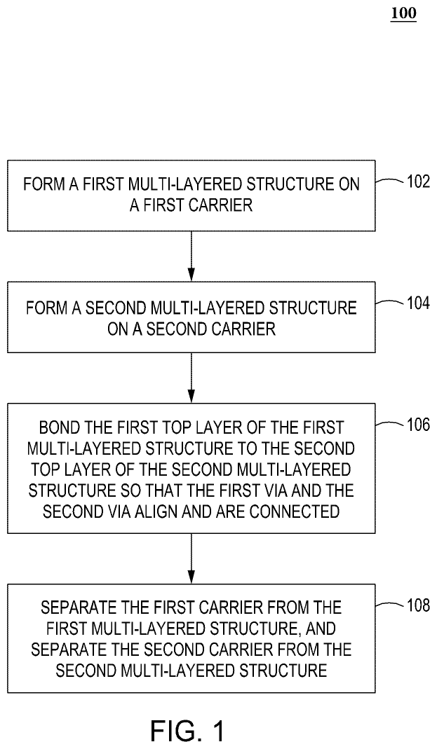

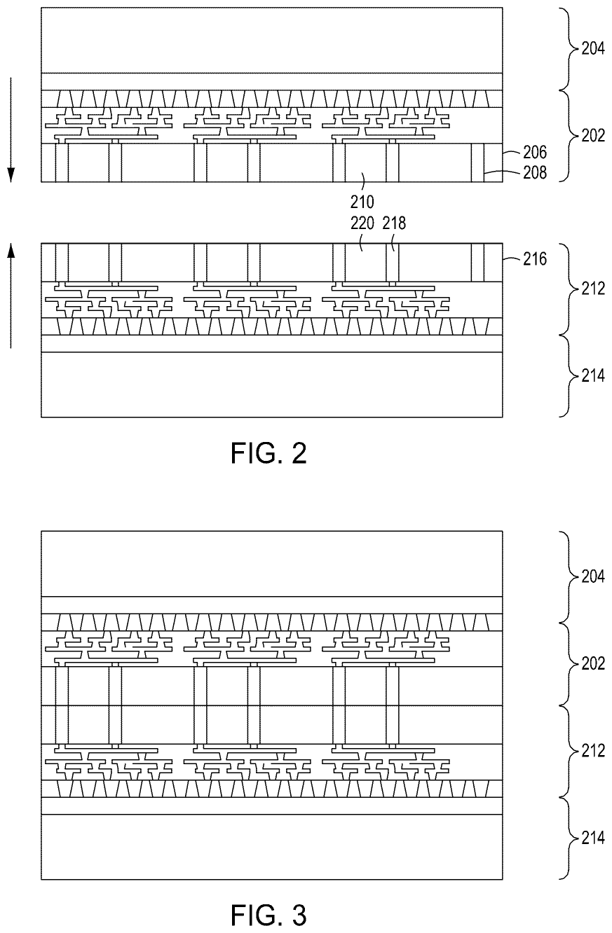

FIG. 1 shows a method 100 for substrate processing in accordance with some embodiments of the present disclosure. At block 102, the method 100 includes forming a first multi-layered structure on a first carrier. The first multi-layered structure includes a first top layer including a core material and at least one first via extending through the core material. FIG. 2 shows a first multi-layered structure 202 formed on a first carrier 204. The first multi-layered structure 202 has a first top layer 206 including a first core material 210 and a plurality of first vias 208 in the first core material 210.

At block 104, the method 100 includes forming a second multi-layered structure on a second carrier. The second multi-layered structure includes a second top layer including the core material and at least one second via extending through the core material. FIG. 2 shows a second multi-layered structure 212 formed on a second carrier 214. The second multi-layered structure 212 has a second top layer 216 including a second core material 220 and a plurality of second vias 218 in the second core material 220.

At block 106, the method 100 includes bonding the first top layer to the second top layer so that the first via and the second via align and are connected, and so that core material 210 and core material 220 are connected. FIG. 3 shows bonding of the first top layer 206 to the second top layer 216 and alignment between the first vias 208 and the second vias 218. In some embodiments, bonding may include a hybrid bonding process during which top layer 206 and top layer 216 may be heated and pressed against each other. This results in the top layers 206 and 216 being fused to each other. The first vias 208 are fused to the second vias 218. The first core material 210 is fused to the second core material 220. The method 100 may also include planarizing the first top layer 206 and the second top layer 216 before bonding.

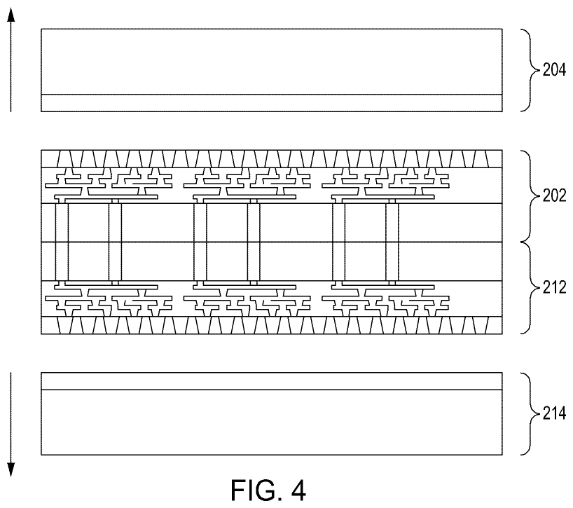

At block 108, the method 100 may include, after bonding, separating the first carrier from the first multi-layered structure, and separating the second carrier from the second multi-layered structure. FIG. 4 shows separating the first carrier 204 from the first multi-layered structure 202 and separating the second carrier 214 from the second multi-layered structure 212. In some embodiments, separating the first carrier 204 and/or the second carrier 214 may include destructively removing the first carrier 204 and/or the second carrier 214, such as by grinding. In some embodiments, separating the first carrier 204 and/or separating the second carrier 214 may include debonding the first carrier 204 and/or the second carrier 214 without damage so that the first carrier 204 and/or the second carrier 214 may be reused. The structure formed by bonding the first multi-layered structure 202 and the second multi-layered structure 212 may be a chip package substrate, such as chip package substrate 1102, on which the interposer 1104 may be attached, as shown in FIG. 11. At least one of chip 1106 or memory chip 1108 may be attached to the interposer 1104. In some embodiments, and a shown in FIG. 11, the interposer 1104 may include an RDL at a connection interface with at least one of chips 1106 or memory chip 1108.

The first multi-layered structure 202 and the second multi-layered structure 212 may be formed using the same processes described herein. The following discussion will refer to the first multi-layered structure 202, but is equally applicable to the second multi-layered structure 212. While the methods for forming the first multi-layered structure 202 may be the same for forming the second multi-layered structure 212, the structure and arrangement of the first multi-layered structure 202 and the second multi-layered structure 212 may be different. The arrangement of the first vias 208 and the second vias 218 are arranged as mirror images so that the first vias 208 and the second vias align.

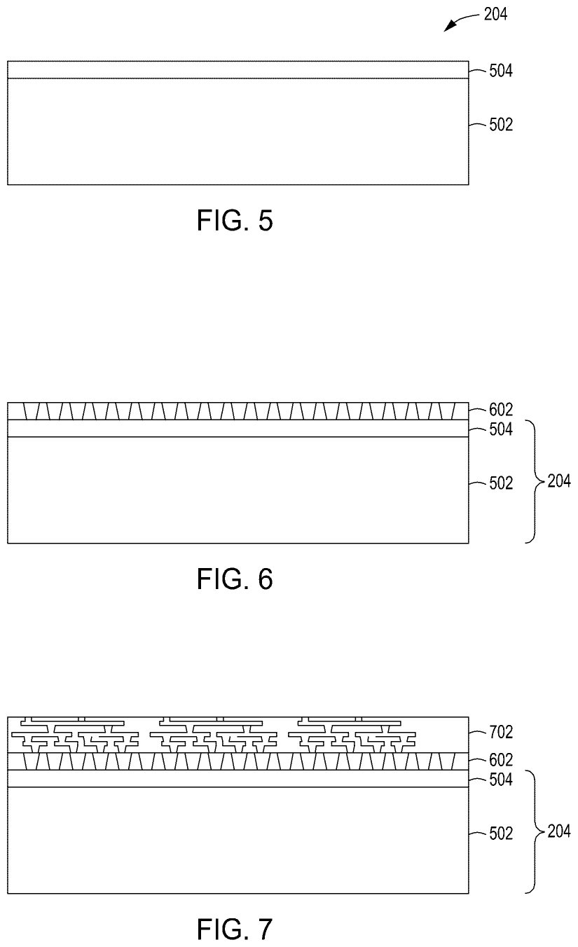

In some embodiments, and as shown in FIG. 5, the method 100 may include providing the first carrier 204, which may include a substrate 502 and a bond layer 504 attached to the substrate 502. The substrate 502 may be a silicon substrate. The bond layer 504 may be a high temperature (HT) bond/de-bond layer configured to permit the bond layer 504 to bond and de-bond at elevated temperature.

In some embodiments, and as shown in FIG. 6, forming the first multi-layered structure 202 may include forming a first inorganic redistribution layer (RDL) 602 on the first carrier. In FIG. 6, the first inorganic RDL 602 is shown bonded to the bond layer 504. The first inorganic RDL 602 may be an inorganic copper dual damascene layer.

In some embodiments, and as shown in FIG. 7, forming the first multi-layered structure 202 may include forming a first organic redistribution layer (RDL) 702 on the first inorganic RDL 602. The first organic RDL may be an Ajinomoto Build-Up Film (ABF) with pattern plated copper or other ABF substrate.

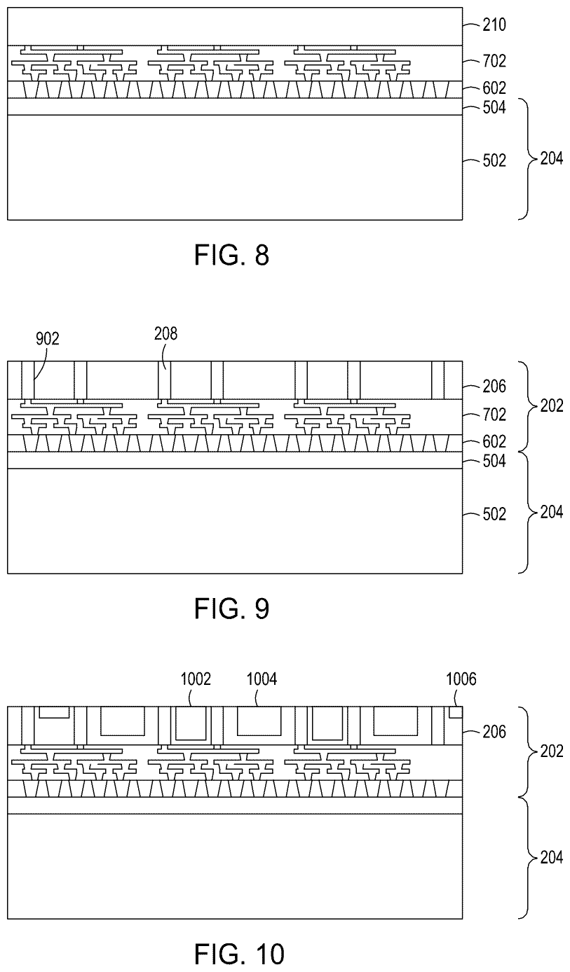

In some embodiments, and as shown in FIGS. 8 and 9, forming the first multi-layered structure 202 may include forming the first top layer 206 on the first organic RDL 702. In FIG. 8, the method 100 includes depositing a layer of the first core material 210 on the first organic RDL 702. In some embodiments, the first core material 210 may be sputter deposited. The first core material 210 may include various materials, including at least one of silicon, oxides, or metals. The total thickness of first core material 210 and the second core material 220 may be about 100 μm to about 1500 μm. In some embodiments, the first top layer 206 and the second top layer 216 may each have a thickness of 50 μm to 760 μm. In some embodiments, the first top layer 206 and the second top layer 216 have a thickness selected based on a desired bow of the first multi-layered structure 202 and the second multi-layered structure 212. In some embodiments, the first multi-layered structure 202 and the second multi-layered structure 212 are constructed to have less than 450 μm of bow to facilitate processing through lithography tools that may be used to print the wires.

In some embodiments, the first core material 210 and the second core material 220 may be the same material. In some embodiments, the first core material 210 and the second core material 220 may be different.

In FIG. 9, the method 100 includes forming a first opening 902 through the first core material 210 and forming (i.e., depositing) the first via 208 in the first opening 902. The first via 208 extends to the first organic RDL 702 and is electrically connected to the first organic RDL 702. The first via 208 may be formed by sputter deposition. The first opening 902 may be formed by laser removal or etching of the first core material 210.

In some embodiments, and as shown in FIG. 10, the method 100 may optionally include embedding at least one of passive electronic components 1002, active electronic components 1004, or a thermal management structure 1006 into the first top layer 206 before bonding. Passive electronic components may include, for example, resistors, capacitors, inductors, and RF coils. Active electronic components may include, for example, diodes and transistors. A thermal management structure may include a passage for liquid or gas heat transfer or a solid heat transfer element.

The methods described herein enable a thinner core which can improve resistance through vias formed in the core. Also, the methods described herein enable inorganic RDL to be deposited before organic RDL on each of the two multi-layered structures, which can allow downstream fabrication in environments with less stringent cleanliness requirements. In addition, the methods described herein may allow reuse of carriers used to fabricate each of the two multi-layered structures, which can result in cost savings and reduced material waste. Also, the methods described herein allow the core material to be deposited as a top layer of each of the two multi-layered structures. As a result, the core material may be easily changed or customized in a deposition process (e.g., sputter deposition) at a later stage of fabrication.

While the foregoing is directed to embodiments of the present disclosure, other and further embodiments of the disclosure may be devised without departing from the basic scope thereof.

1. A method for substrate processing, the method comprising:
forming a first multi-layered structure on a first carrier, wherein the first multi-layered structure includes a first top layer including a first core material and at least one first via extending through the first core material;
forming a second multi-layered structure on a second carrier, wherein the second multi-layered structure includes a second top layer including a second core material and at least one second via extending through the second core material;
bonding the first top layer to the second top layer so that the first via and the second via align and are connected; and
after bonding, separating the first carrier from the first multi-layered structure, and separating the second carrier from the second multi-layered structure.

2. The method of claim 1, wherein the first carrier and the second carrier each include a corresponding substrate and a corresponding bond layer removably attached to the corresponding substrate.

3. The method of claim 1, wherein:
forming the first multi-layered structure includes forming a first inorganic redistribution layer on the first carrier, forming a first organic redistribution layer on the first inorganic redistribution layer, and forming the first top layer on the first organic redistribution layer, and
forming the second multi-layered structure includes forming a second inorganic redistribution layer on the second carrier, forming a second organic redistribution layer on the second inorganic redistribution layer, and forming the second top layer on the second organic redistribution layer.

4. The method of claim 3, wherein the first inorganic redistribution layer and the second inorganic redistribution layer are dual damascene layers.

5. The method of claim 3, wherein the first organic redistribution layer and the second organic redistribution layer are ABF.

6. The method of claim 3, wherein the first core material and the second core material include at least one of silicon, oxide, or metal.

7. The method of claim 3, wherein forming the first top layer and the second top layer includes sputter depositing the first core material and the second core material.

8. The method of claim 7, wherein:
forming the first top layer includes forming a first opening through the first core material of the first top layer and forming the first via in the first opening, wherein the first via extends to the first organic redistribution layer, and
forming the second top layer includes forming a second opening through the second core material of the second top layer and forming the second via in the second opening, wherein the second via extends to the second organic redistribution layer.

9. The method of claim 8, wherein forming the first opening and forming the second opening include at least one of laser removal or etching of the first core material and the second core material.

10. The method of claim 1, further comprising planarizing the first top layer and the second top layer before bonding.

11. The method of claim 1, further comprising embedding passive electronic components into at least one of the first top layer or the second top layer before bonding.

12. The method of claim 1, further comprising embedding active electronic components into at least one of the first top layer or the second top layer before bonding.

13. The method of claim 1, further comprising embedding a thermal management structure into at least one of the first top layer or the second top layer before bonding.

14. The method of claim 1, wherein the first core material and the second core material are connected during the bonding.

15. The method of claim 14, wherein bonding includes hybrid bonding.

16. The method of claim 1, wherein the first top layer and the second top layer each has a thickness of 50 μm to 760 μm.

17. The method of claim 1, wherein the first multi-layered structure and the second multi-layered structure form a chip package substrate.

18. The method of claim 17, further comprising attaching an interposer to the chip package substrate.

19. The method of claim 18, further comprising attaching a chip to the interposer.

20. The method of claim 19, wherein the chip is a memory chip.
